(19) United States
(12) Patent Application Publication
(10) Pub. No.: US 2013/0179103 A1
(43) Pub. Date: Jul. 11, 2013

(54) BATTERY ANALYSIS DEVICE AND METHOD THEREOF

(71) Applicants: Yi-Feng Luo, Yilan County (TW); Kai-Cheung Juang, Hsinchu (TW); Yung-Hsi Chang, Hsinchu County (TW); Chueh-Hao Yu, Yunlin County (TW)

(72) Inventors: Yi-Feng Luo, Yilan County (TW); Kai-Cheung Juang, Hsinchu (TW); Yung-Hsi Chang, Hsinchu County (TW); Chueh-Hao Yu, Yunlin County (TW)

(73) Assignee: INDUSTRIAL TECHNOLOGY RESEARCH INSTITUTE, Hsinchu (TW)

(21) Appl. No.: 13/439,405

(22) Filed: Apr. 4, 2012

(30) Foreign Application Priority Data
Jan. 6, 2012 (TW) 101100639

(51) Int. Cl. G06F 19/00; G01R 31/36

(52) U.S. Cl. 702/63

(57) ABSTRACT

A battery analysis device for a battery module having at least one battery cell includes a power source supply unit, a signal capturing unit, a signal adjusting unit, a frequency domain analyzing unit, a time domain analyzing unit, and a processing unit. The power source supply unit provides a variable-frequency voltage signal to a battery cell. The signal capturing unit captures a current signal generated by a battery cell in response to the variable-frequency voltage signal. The signal adjusting unit adjusts the variable-frequency voltage signal and the current signal. The frequency domain analyzing unit and time domain analyzing unit analyze both the adjusted variable-frequency voltage signal and the adjusted current signal in frequency domain and time domain respectively for obtaining a frequency domain parameter and a time domain parameter. The processing unit obtains electrochemistry characteristics of the battery cell according to the frequency and the time domain parameters.

### CROSS-REFERENCE TO RELATED APPLICATIONS

This non-provisional application claims priority under 35 U.S.C. §119(a) on Patent Application No(s). 101100639 filed in Taiwan, R.O.C. on Jan. 6, 2012, the entire contents of which are hereby incorporated by reference.

### BACKGROUND

1. Technical Field

The disclosure relates to battery analysis technology, and more particularly to a real time online batter analysis device and a method thereof.

2. Related Art

With development of vehicle technology, interpersonal distance is reduced and human's life quality is improved. Vehicles drove by oil have an engine using liquid fuel. It is not difficult to measure the remaining amount of fuel in a vehicle. However, with awareness of environmental protection and in order to avoid excessive dependence on oil, people have focused on electric vehicles (EVs) which have low noise, low environmental pollution, easily controlled pollution sources, and diverse kinds of energy.

Generally, EVs are drove by electrical energy stored in a battery. A charge and discharge processes with large current often exit in EVs. It is not easy to accurately measure the remaining electrical quantity of a battery and thus it is very important to manage and analyze the battery. State of charge (SOC) and state of healthy (SOH) of a battery can be reflected by variation of internal impedance of a battery. Therefore, the SOC and SOH of a battery can be measured by direct current (DC) internal impedance and a temperature of the battery. The SOC shows the remaining electrical quantity of a battery. The SOH shows a state parameter of a battery, and the state parameter is a parameter quantifying the internal impedance variation of the battery resulting from ageing phenomenon. Therefore, a user may know an appropriate time to charge and replace a battery by checking the SOC and the SOH of the battery, respectively.

A method for checking the SOH of a battery mostly uses impedance tracking technology, i.e., using DC impedance and open circuit voltage to calculate the chemistry capacity of a battery and then with assistance of a look-up table estimating the SOC and SOH of the battery. Furthermore, the open circuit voltage is not measured when a battery is in off-line state, and thus the accuracy for the SOC and SOH obtained by means of look-up table is debatable. Actually, the open circuit voltage needs to be measured when a battery is idle or has a light load. Furthermore, only in a particular charge or discharge process the capacity of a battery can be updated. That is, information regarding the SOC and SOH of a battery cannot be obtained in real time. In view of above, there has been a key problem for how to obtain the internal parameters of a battery in a real time and thus deduce the SOC and SOH of the battery.

### SUMMARY

The present disclosure provides a battery analysis device for a battery module having at least one battery cell, comprising: a power source supply unit for providing a variable-frequency voltage signal to the at least one battery cell, the variable-frequency voltage signal having a plurality of frequencies in a range between a first frequency and a second frequency; a signal capturing unit for capturing a current signal generated by the at least one battery cell in response to the variable-frequency voltage signal; a signal adjusting unit connected to the power source supply unit and the signal capturing unit for receiving and adjusting the variable-frequency voltage signal and the current signal to generate an adjusted variable-frequency voltage signal and an adjusted current signal; a frequency domain analyzing unit connected to the signal capturing unit for receiving and analyzing in frequency domain the adjusted variable-frequency voltage signal and the adjusted current signal to obtain a frequency domain parameter; a time domain analyzing unit connected to the signal capturing unit for receiving and analyzing in time domain the adjusted variable-frequency voltage signal and the adjusted current signal to obtain a time domain parameter; and a processing unit connected to the frequency domain analyzing unit and the time domain analyzing unit for receiving the frequency domain parameter and the time domain parameter and obtaining electrochemistry characteristics of the at least one battery cell based on the frequency domain parameter and the time domain parameter.

The present disclosure further provides a battery analysis method for a battery module having at least one battery cell, comprising: providing a variable-frequency voltage signal to the at least one battery cell, the variable-frequency voltage signal having a plurality of frequencies in a range between a first frequency and a second frequency; capturing a current signal generated by the at least one battery cell in response to the variable-frequency voltage signal; adjusting the variable-frequency voltage signal and the current signal to generate an adjusted variable-frequency voltage signal and an adjusted current signal; analyzing in frequency domain the adjusted variable-frequency voltage signal and the adjusted current signal to obtain a frequency domain parameter; analyzing in time domain the adjusted variable-frequency voltage signal and the adjusted current signal to obtain a time domain parameter; and obtaining electrochemistry characteristics of the at least one battery cell based on the frequency domain parameter and the time domain parameter.

### BRIEF DESCRIPTION OF THE DRAWINGS

The present disclosure will become more fully understood from the detailed description given here in below for illustration only, and thus are not limitative of the present disclosure, and wherein:

FIG. 1 is a block diagram for a battery analysis device according to the present disclosure;

FIG. 2 is a block diagram for an equivalent module for a battery cell according to the present disclosure;

FIG. 3 a block diagram for another battery analysis device according to the present disclosure;

FIG. 4 a flowchart for a battery analysis method according to the present disclosure; and

FIG. 5 is a flowchart for another battery analysis method according to the present disclosure.

### DETAILED DESCRIPTION

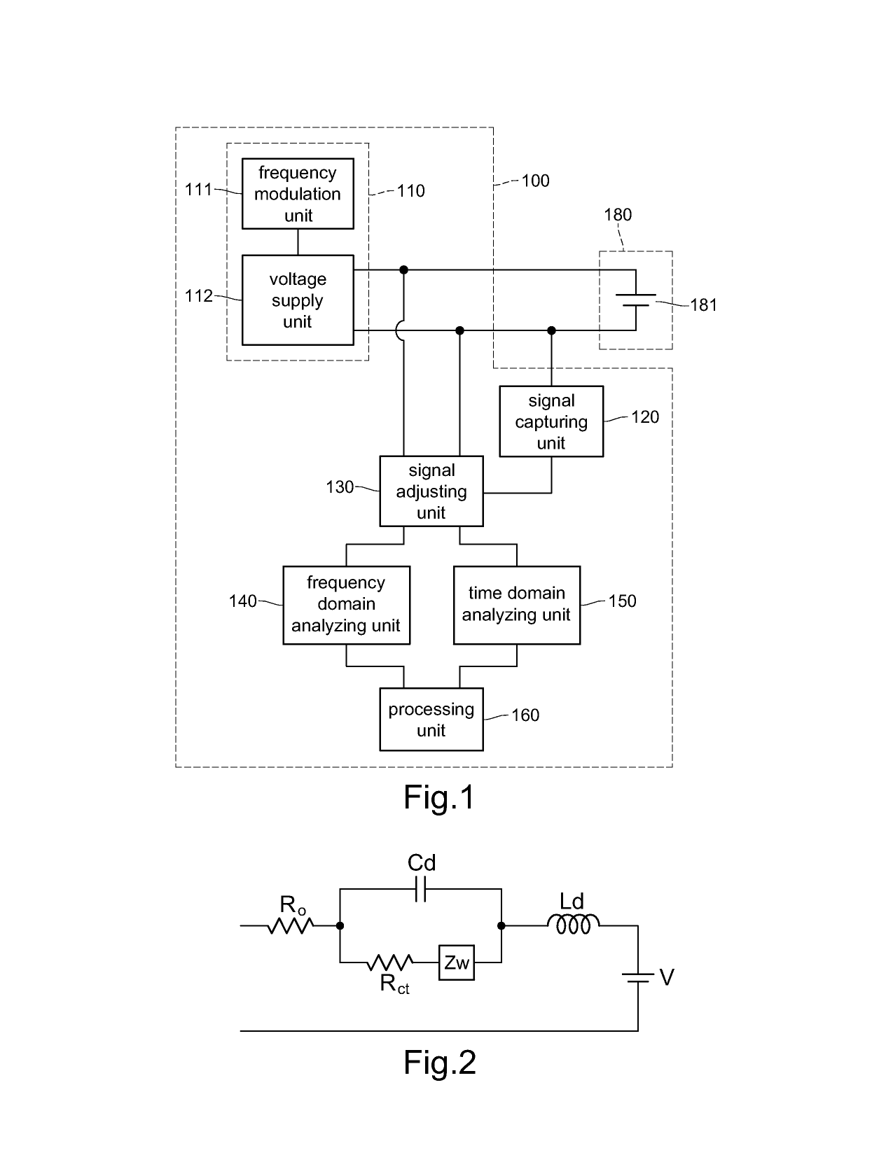

FIG. 1 is a block diagram for a battery analysis device according to the present disclosure. With reference to FIG. 1, the battery analysis device 100 in the embodiment is adapted to the battery module 180 including a battery cell 181. The battery analysis device 100 includes a power source supply unit 110, a signal capturing unit 120, a signal adjusting unit 130, a frequency domain analyzing unit 140, a time domain analyzing unit 150, and a processing unit 160.

The power source supply unit 110 is used to provide a variable-frequency voltage signal having a plurality of frequencies in a range between a first frequency and a second frequency to the battery cell 181. The first frequency is different from the second frequency. For example, the second frequency is greater than the first frequency.

For illustration, if the first frequency is 1 Hz and the second frequency is 100 Hz, then the variable-frequency voltage signal has multiple frequencies in the range between 1 Hz and 100 Hz. In an embodiment, the multiple frequencies are for example 1 Hz (the first frequency), 2 Hz, 3 Hz . . . 99 Hz, and 100 Hz (the second frequency) in sequence. That is, the variable-frequency voltage signal has 100 frequencies with a frequency interval of 1 Hz. When the battery analysis device 100 starts to work, the power source supply unit 100 provides a variable-frequency voltage signal having the first frequency of 1 Hz to the battery cell 181 and then provides a variable-frequency voltage signal having the frequency of 2 Hz, 3 Hz, and so on until the second frequency of 100 Hz to the battery cell 181 by means of varying the frequency of the variable-frequency voltage signal with the frequency interval of 1 Hz at a time. In such a way, the battery cell 181 is disturbed.

In another embodiment, the variable-frequency voltage signal has multiple frequencies, for example, 1 Hz (the first frequency), 50 Hz, and 100 Hz (the second frequency) in sequence. That is, the variable-frequency voltage signal has three different frequencies with a frequency interval of 50 Hz. The number of frequencies of the variable-frequency voltage signal and the frequency interval may be adjusted according to a user's requirement but not limited thereto.

The signal capturing unit 120 is used to capture a current signal generated by the battery cell 181 in response to the variable-frequency voltage signal. In particular, after the batter cell 181 receives the variable-frequency voltage signal, the signal capturing unit 120 captures the current signal, for example, the amplitude and the phase of the current signal, generated by the battery cell 181 for subsequent operation.

The signal adjusting unit 130 connected to the power source supply unit 110 and the signal capturing unit 120 is used to receive and adjust the variable-frequency voltage signal and the current signal to output an adjusted variable-frequency voltage signal and an adjusted current signal. For example, the signal adjusting unit 130 may amplify the variable-frequency voltage signal and the current signal for subsequent analyzing operation.

The frequency domain analyzing unit 140 connected to the signal capturing unit 130 is used to receive and analyze in frequency domain the adjusted variable-frequency voltage signal and the adjusted current signal so as to obtain a frequency domain parameter. In the other hand, the time domain analyzing unit 150 connected to the signal capturing unit 130 is used to receive and analyze in time domain the adjusted variable-frequency voltage signal and the adjusted current signal so as to obtain a time domain parameter.

The processing unit 160 connected to the frequency domain analyzing unit 140 and the time domain analyzing unit 150 is used to obtain electrochemistry characteristics of the battery cell 181 according to the frequency domain parameter and the time domain parameter. The equivalent module for the battery cell 181 is shown as FIG. 2. Electrochemistry characteristics of the battery cell 181 may be deduced by the following equations (1) and (2).

$$\begin{matrix}\frac{{V}_{max} sin ( 2 π {f}_{n} t )}{{I}_{n} sin ( 2 π {f}_{n} t - {φ}_{n} )} = {Z}_{n} {∠φ}_{n} & ( 1 ) \\ {Z}_{n} {∠φ}_{n} = {R}_{n} \pm j {X}_{n} & ( 2 )\end{matrix}$$

where Vₘₐₓ sin(2πfₙt) is the variable-frequency voltage signal, Iₙ sin(2πfₙt−φₙ) is the current signal generated by the battery cell 181 in response to the variable-frequency voltage signal, Zₙ is an impedance value of the battery cell 181, φₙ is a phase, Rₙ is the real part of Z_{b}∠φₙ and Rₙ may correspond to DC impedance Rₒ, electrode-electrolyte resistance R_{ct}, and Warburg impedance Z_{w} for the equivalent module of the battery cell 181, Xₙ is the imaginary part of Zₙ∠φₙ and Xₙ may correspond to capacitance C_{d}, inductance L_{d}, and Warburg impedance Z_{w} for the equivalent module of the battery cell 181, V is the ideal voltage of the battery cell 181, and n is a positive integer greater than or equal to 1 representing different cases with different frequencies.

For example, when n=1, it means that each parameter above is obtained by using the frequency value as 1 Hz (the first frequency), when n=2, it means that each parameter above is obtained by using the frequency value as 2 Hz, and the like until the case in which n=100. In this way, more internal parameters of the battery cell 181 can be achieved more accurately, so that the SOC and the SOH of the battery module 180 can be determined more accurately.

After obtaining the electrochemistry characteristics of the battery cell 181, the processing unit 160 can estimate the SOC and the SOH of the battery cell 181 according to the electrochemistry characteristics and a temperature signal (e.g., the temperature may be the environmental temperature measured when analyzing the battery cell 181). In such a way, a real-time online measurement can be achieved to estimate the SOC and the SOH of the battery module 180, without the assistance of a battery database. Also, the estimated SOC and SOH of the batter module 180 can be provided to the back-end system so that a user may replace a battery in time.

In this embodiment, the battery analysis device 100 may analyze the battery cell 181 of the battery module 180 in real time in an online manner and immediately provide the SOC and the SOH of the battery cell 181 so as to accelerate analyzing the battery module.

The equivalent module for the battery cell 181 shown in FIG. 2 is merely one example of this embodiment but not limited thereto. There are other equivalent examples based on this embodiment disclosed herein. Each example for the internal module of the battery cell 181 has equivalent DC impedance, electrode-electrolyte resistance R_{ct}, Warburg impedance Z_{w}, capacitance C_{d}, and inductance L_{d}.

In addition, the power source supply unit 110 includes a frequency modulation unit 111 and a voltage supply unit 112. The frequency modulation unit 111 is used to provide to multiple frequencies in a range between the first frequency and the second frequency. The voltage supply unit 112 connected to the frequency modulation unit 111 is used to provide the variable-frequency voltage signal according to the multiple frequencies.

Furthermore, the battery analysis device 100 can be configured on a chip by means of Integrated Circuit (IC) design or on any electronic devices (e.g., smart phone, tablet computer, and laptop) or electrical vehicles having a battery, so that the SOC and the SOH of the battery can be estimated in real time and thus a user may repalce the battery in time.

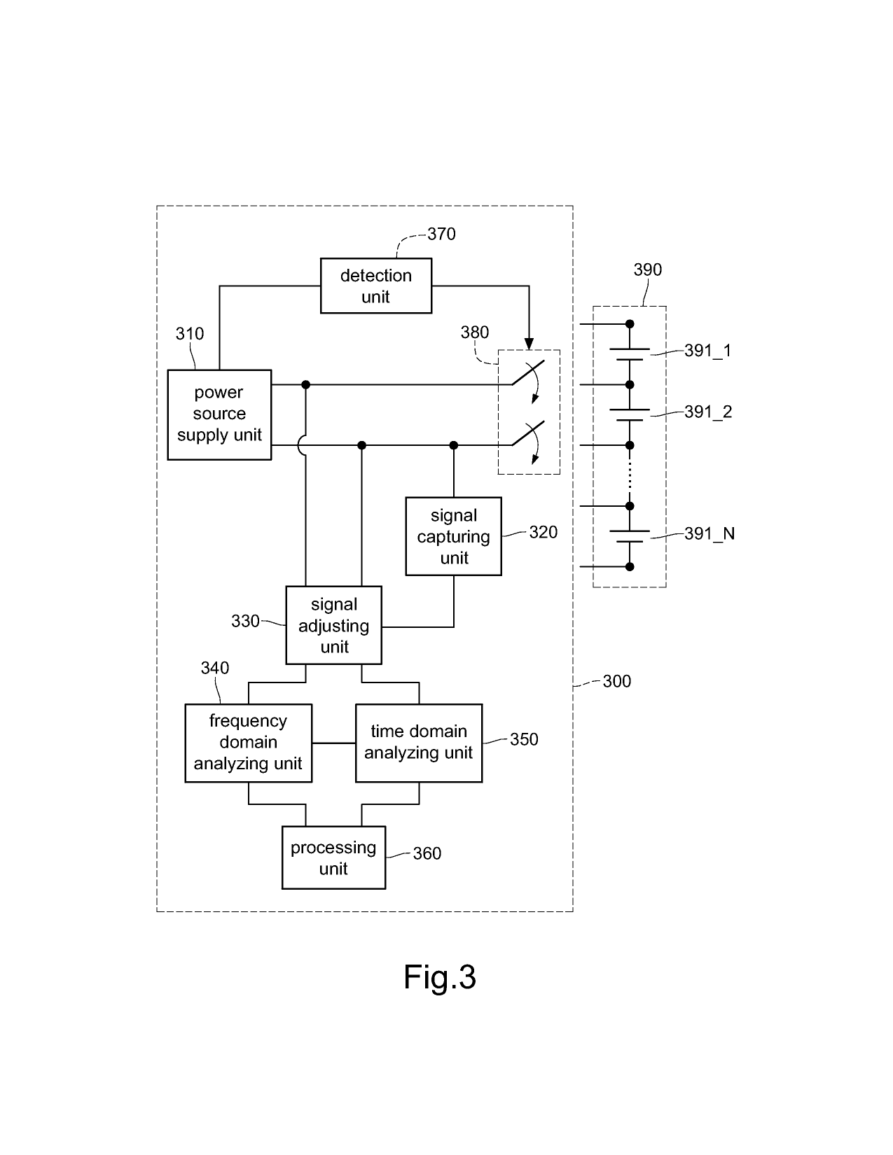

FIG. 3 is a block diagram for another battery analysis device according to the present disclosure. With reference to FIG. 3, the battery analysis device 300 is adapted to a battery module 380 which have a plurality of battery cells 391_1˜392_N, where N is a positive integer greater than 1. The battery analysis device 300 includes a power source supply unit 310, a signal capturing unit 320, a signal adjusting unit 330, a frequency domain analyzing unit 340, a time domain analyzing unit 350, a processing unit 360, a detection unit 370, and a switching unit 380.

In this embodiment, the operation and connection for the power source supply unit 310, the signal capturing unit 320, the signal adjusting unit 330, the frequency domain analyzing unit 340, the time domain analyzing unit 350, and the processing unit 360 may be referenced to those for the corresponding units shown in FIG. 2, and here will not be described again in detail. The internal structure and operation for the power source supply unit 310 may be referenced to that of the power source supply unit 110 shown in FIG. 1(shown as the frequency modulation unit 111 and the voltage supply unit 112), and will not be described again in detail.

The detection unit 370 connected to the power source supply unit 310 is used to detect whether a frequency of the variable-frequency voltage signal is equal to the second frequency and thus output a detection signal. The switching unit 380 connected to the detection unit 370 and the power source supply unit 310 is used to sequentially switch the variable-frequency voltage signal to battery cells 391_1˜391_N according to the detection signal.

For example, when the device 300 and the battery module 390 are connected to start an analyzing operation, the power source supply unit 310 provides the variable-frequency voltage signal with its frequency varying from the first frequency to the second frequency. For example, the frequency of the variable-frequency voltage signal is 1 Hz (the first frequency), 2 Hz, . . . , 99 Hz, and 100 Hz (the second frequency) in sequence. The switching unit 380 firstly switches the variable-frequency voltage signal to connect the battery cell 391_1 so as to provide the variable-frequency voltage signal to the battery cell 391_1. The battery cell 391_1 generates a required current signal in response to the variable-frequency voltage signal for subsequent operation.

Then the detection unit 370 detects whether a frequency of the variable-frequency voltage signal is equal to the second frequency (e.g., 100 Hz). If the detected frequency is not equal to the second frequency, it means that the variable-frequency voltage signal has not finished disturbing the battery cell 391_1 (i.e., the frequency has not varied to the second frequency from the first frequency). The detection unit 370 will not generate a detection signal to make the switching unit 380 keep connected with the battery cell 391_1.

At this time, the variable-frequency voltage signal continues varying. If a detected frequency of the variable-frequency voltage signal is equal to the second frequency, it means that the variable-frequency voltage signal has finished disturbing the battery cell 391_1. The detection unit 370 generates a detection signal to the switching unit 380. Then, the switching unit 380 switches the variable-frequency voltage signal to connect the battery cell 391_2 to provide the variable-frequency voltage signal to the cell 391_2. The battery cell 391_2 generates a required current signal in response to the variable-frequency voltage signal for subsequent operation.

Subsequently, if detecting that a frequency of the variable-frequency voltage signal is not equal to the second frequency, the detection unit 370 will not generate a detection signal to the switching unit 380 to make the switching unit 380 keep connected to the battery cell 391_2. Then, the frequency of the variable-frequency voltage signal continues to vary until getting to the second frequency. If detecting that a frequency of the variable-frequency voltage signal is equal to the second frequency, the detection unit 370 generates a detection signal to the switching unit 380. The switching unit 380 switches the variable-frequency voltage signal to connect the battery cell 391_3 and the cell 391_2 generates a required current signal in response to the variable-frequency voltage signal for subsequent operation. In such a way, all battery cells 391_1˜391_N will generate corresponding required current signals according to the variable-frequency voltage signal until the switching unit 380 switches the variable-frequency voltage signal to connect the battery cell 391_N.

The signal capturing unit 320 sequentially captures the multiple current signals generated by battery cells 391_1˜391_N in response to variable-frequency voltage signals. The signal adjusting unit 330 receives and adjusts variable-frequency voltage signals and the multiple current signals to generate adjusted variable-frequency voltage signals and adjusted current signals. The frequency domain analyzing unit 340 analyzes in frequency domain the adjusted variable-frequency voltage signals and adjusted current signals to obtain multiple frequency domain parameters. The time domain analyzing unit 350 analyzes in time domain the adjusted variable-frequency voltage signals and adjusted current signals to obtain multiple time domain parameters. Finally, the processing unit 360 obtains electrochemistry characteristics of battery cells 391_1˜391_N according to the multiple time domain parameters and the multiple frequency domain parameters. Therefore, more internal parameters of battery cells 391_1˜391_N can be achieved more accurately.

Then the processing unit 360 can estimate SOC and SOH of battery cells 391_1˜391_N according to electrochemistry characteristics of battery cells 391_1˜391_N and a temperature signal (e.g., the temperature may be an environmental temperature measured when analyzing the battery module 390). In such a way, even if batteries are idle or have a light load, a real-time online measurement can be achieved to estimate the SOC and the SOH of the battery module 390, without the assistance of a battery database. Also, the estimated SOC and SOH of the batter module 390 can be provided to the back-end system so that a user may replace a battery in time.

In this embodiment, the battery analysis device 300 may analyze battery cells 391_1˜391_N of the battery module 390 in real time in an online manner and immediately provide SOC and SOH of battery cells 391_1˜391_N so as to accelerate the analyzing.

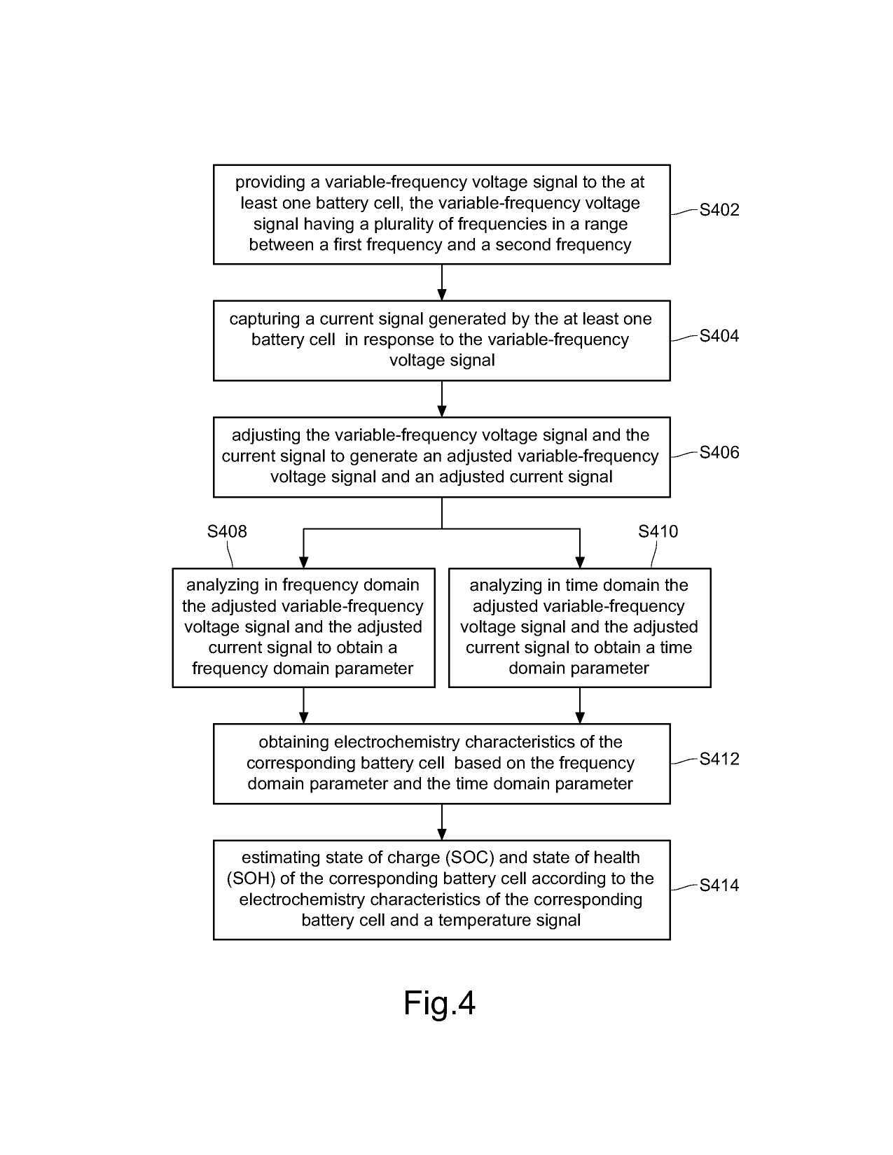

It can be concluded a battery analysis method based on the embodiment described with reference to FIG. 1. FIG. 4 is a flowchart for a battery analysis method. The method is adapted for a battery module comprising at least one battery cell. In the step S402, a variable-frequency voltage signal with multiple frequencies in a range between a first frequency and a second frequency is provided to a battery cell. In the step S404, a current signal generated in response to the variable-frequency voltage signal is captured.

In the step S406, the variable-frequency voltage signal and the current signal are adjusted to output the adjusted variable-frequency voltage signal and the adjusted current signal. In the step S408, the adjusted variable-frequency voltage signal and the adjusted current signal are analyzed in frequency domain to obtain frequency domain parameters. In the step S410, the adjusted variable-frequency voltage signal and the adjusted current signal are analyzed in time domain to obtain time domain parameters. In the step S412, electrochemistry characteristics of the battery cell are obtained according to the frequency domain parameters and the time domain parameters. In the step S414, the SOC and the SOH are estimated according to electrochemistry characteristics of the battery cell.

In this embodiment, the battery analysis method may analyze a battery cell of a battery module in real time in an online manner and immediately provide SOC and SOH of the battery cell so as to accelerate the analyzing.

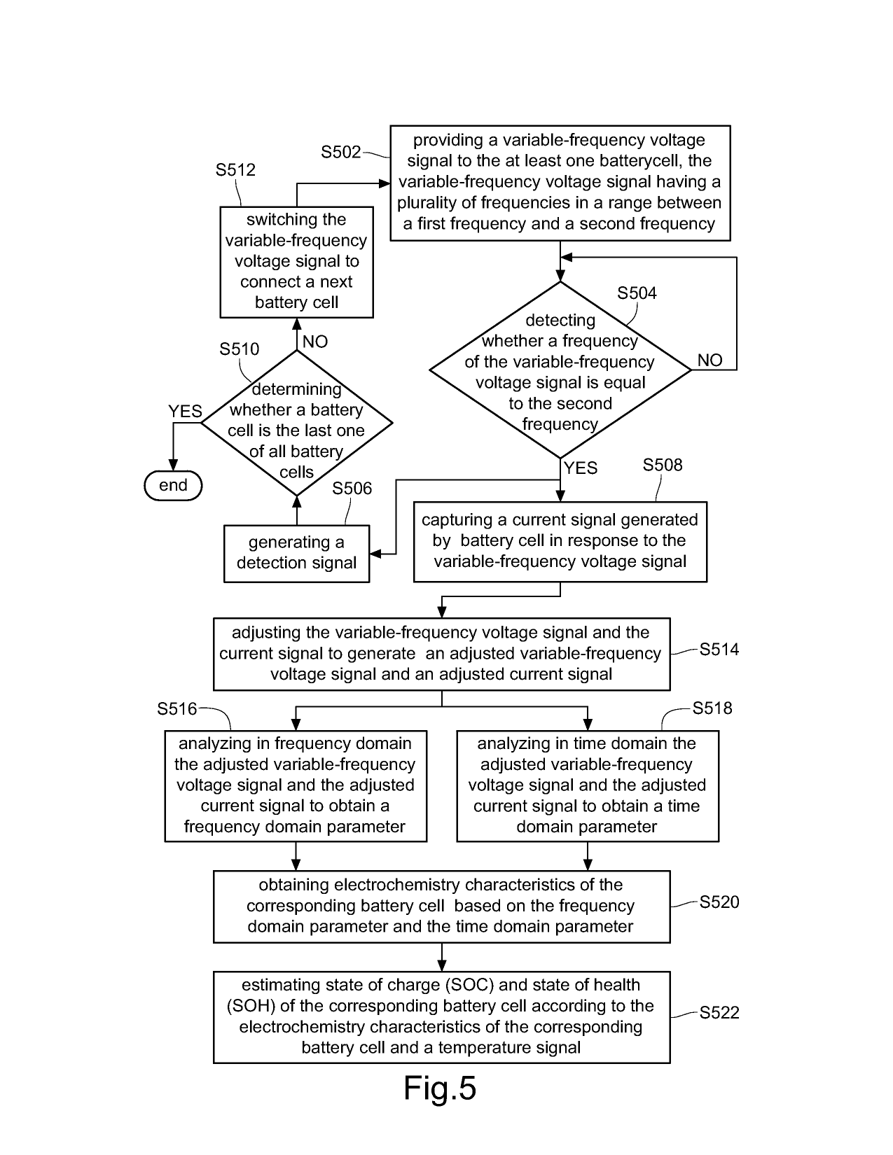

It can be conducted another battery analysis method based on the embodiment described with reference to FIG. 2. FIG. 5 is a flowchart for another battery analysis method according to the present disclosure. The method in this embodiment is adapted for a battery module having multiple battery cells.

In the step 502, a variable-frequency voltage signal with multiple frequencies in a range between a first frequency and a second frequency is provided to battery cells. In the step S504, the frequency of the variable-frequency voltage signal is detected to determine whether the detected frequency is equal to the second frequency. If the detected frequency is not equal to the second frequency, the method goes to the step S504 to detect again whether the frequency of the variable-frequency voltage signal is equal to the second frequency until detecting that the frequency of the variable-frequency voltage signal is equal to the second frequency. Then, the method goes to the steps S506 and S508.

As described above, if detecting that the frequency of the variable-frequency voltage signal is equal to the second frequency, the process goes to the steps S506 and S508, so as to generate a detection signal and capture current signals generated by battery cells in response to variable-frequency voltage signals. The step S510 is performed after the step S506 to determine whether the current battery cell is the last one. If it is, the analyzing process ends. It means that analyzing operation for all battery cells in the battery module has finished. If it is not, the process goes to the step S512 to make the variable-frequency voltage signal switch to connect a next battery cell according to the detection signal. Then, the process returns to the step S502 to analyzing another battery cell.

In the other hand, the step S514 is performed after the step S508 to adjust the variable-frequency voltage signal and the current signal to generate the adjusted variable-frequency voltage signal and the adjusted current signals. In the step S516, the adjusted variable-frequency voltage signal and the adjusted current signals are analyzed in frequency domain to obtain frequency domain parameters. In the Step S18, the adjusted variable-frequency voltage signal and the adjusted current signals are analyzed in time domain to obtain time domain parameters. In the step S520, electrochemistry characteristics of battery cells are obtained according to the frequency domain parameters and the time domain parameters. In the step S522, SOC and SOH of battery cells are estimated according to the electrochemistry characteristics and a temperature signal.

In such a way, the battery analysis method may use online measurements in real time to obtain the internal parameters of each battery cell of a battery module, and thus improve the accuracy of battery analysis.

In this embodiment, the battery analysis method may analyze battery cells of a battery module in real time in an online manner and provide immediately SOC and SOH of battery cells so as to accelerate the analyzing.

The battery analysis device and the method thereof according to the present disclosure provide a variable-frequency voltage signal having frequencies varying from the first frequency to the second frequency to at least battery cell of the battery module. The battery cell generates current signals in response to the variable-frequency voltage signal. The current signals and the variable-frequency voltage signal are analyzed in frequency domain and time domain to obtain electrochemistry characteristics of the battery cell (e.g., the internal parameters. Based on the electrochemistry characteristics and the current temperature, the SOC and SOH of a battery is estimated. In this case, even if a battery is idle or has a light load, real time online measurements and more internal parameters can be achieved to estimate the SOC and the SOH of the battery cell. Furthermore, the method and device can provide the SOC and the SOH for users to know the usage condition of the battery more accurately and replace a battery in time.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A battery analysis device for a battery module having at least one battery cell, comprising:
a power source supply unit for providing a variable-frequency voltage signal to the at least one battery cell, the variable-frequency voltage signal having a plurality of frequencies in a range between a first frequency and a second frequency;
a signal capturing unit for capturing a current signal generated by the at least one battery cell in response to the variable-frequency voltage signal;
a signal adjusting unit connected to the power source supply unit and the signal capturing unit for receiving and adjusting the variable-frequency voltage signal and the current signal to generate an adjusted variable-frequency voltage signal and an adjusted current signal;
a frequency domain analyzing unit connected to the signal capturing unit for receiving and analyzing in frequency domain the adjusted variable-frequency voltage signal and the adjusted current signal to obtain a frequency domain parameter;
a time domain analyzing unit connected to the signal capturing unit for receiving and analyzing in time domain the adjusted variable-frequency voltage signal and the adjusted current signal to obtain a time domain parameter; and
a processing unit connected to the frequency domain analyzing unit and the time domain analyzing unit for receiving the frequency domain parameter and the time domain parameter and obtaining electrochemistry characteristics of the at least one battery cell based on the frequency domain parameter and the time domain parameter.

2. The battery analysis device according to claim 1, wherein the processing unit further estimates state of charge (SOC) and state of health (SOH) of the at least one battery cell according to the electrochemistry characteristics of the battery cell and a temperature signal.

3. The battery analysis device according to claim 1, wherein the power source supply unit comprising:
a frequency modulation unit for providing the plurality of frequencies; and
a voltage supply unit connected to the frequency modulation unit for generating the variable-frequency voltage signal according to the plurality of frequencies.

4. The battery analysis device according to claim 1, wherein the at least one battery cells in the battery module comprising more than one battery cells, the battery analysis device further comprising:
a detection unit connected to the power source supply unit for detecting whether a frequency of the variable-frequency voltage signal is equal to the second frequency and thus generating a detection signal; and
a switching unit connected to the detection unit and the power source supply unit for sequentially switching the variable-frequency voltage signal to the more than one battery cells according to the detection signal;
wherein the signal capturing unit captures a plurality of current signals generated by the more than one battery cells in response to the variable-frequency voltage signal, the signal adjusting unit receives and adjusts the variable-frequency voltage signal and the plurality of current signals to generate an adjusted variable-frequency voltage signal and adjusted plurality of current signals, the frequency domain analyzing unit analyzes in frequency domain the adjusted variable-frequency voltage signal and the adjusted plurality of current signals to obtain a plurality of frequency domain parameters, the time domain analyzing unit analyzes in time domain the adjusted variable-frequency voltage signal and the adjusted plurality of current signals to obtain a plurality of time domain parameters, and the processing unit receives the plurality frequency domain parameters and the plurality time domain parameters to obtain electrochemistry characteristics of the more than one battery cells according to the plurality frequency domain parameters and the plurality time domain parameters.

5. The battery analysis device according to claim 4, wherein the processing unit further estimates state of charge (SOC) and state of health (SOH) of the more than one battery cells according to the electrochemistry characteristics of the more than one battery cells and a temperature signal.

6. The battery analysis device according to claim 1, wherein the battery analysis device analyzes the battery module in real time in an online manner.

7. The battery analysis device according to claim 1, wherein the battery analysis device can be configured on a chip by means of Integrated Circuit (IC) design or on any electronic devices having batteries.

8. A battery analysis method for a battery module having at least one battery cell, comprising:
providing a variable-frequency voltage signal to the at least one battery cell, the variable-frequency voltage signal having a plurality of frequencies in a range between a first frequency and a second frequency;
capturing a current signal generated by the at least one battery cell in response to the variable-frequency voltage signal;
adjusting the variable-frequency voltage signal and the current signal to generate an adjusted variable-frequency voltage signal and an adjusted current signal;
analyzing in frequency domain the adjusted variable-frequency voltage signal and the adjusted current signal to obtain a frequency domain parameter;
analyzing in time domain the adjusted variable-frequency voltage signal and the adjusted current signal to obtain a time domain parameter; and
obtaining electrochemistry characteristics of the at least one battery cell based on the frequency domain parameter and the time domain parameter.

9. The battery analysis method according to claim 8, further comprising:
estimating state of charge (SOC) and state of health (SOH) of the at least one battery cell according to the electrochemistry characteristics of the battery cell and a temperature signal.

10. The battery analysis method according to claim 8, wherein the step of providing a variable-frequency voltage signal to the at least one battery cell further comprising:
providing the plurality of frequencies; and
generating the variable-frequency voltage signal having the plurality of frequencies according to the plurality of frequencies.

11. The battery analysis method according to claim 8, wherein the at least one battery cells in the battery module comprising more than one battery cells, the battery analysis method further comprising:
detecting whether a frequency of the variable-frequency voltage signal is equal to the second frequency;
if the frequency of the variable-frequency voltage signal is not equal to the second frequency, returning to the step of detecting whether the frequency of the variable-frequency voltage signal is equal to the second frequency;
if the frequency of the variable-frequency voltage signal is equal to the second frequency, generating a detection signal and going to the step of capturing the current signal generated by the at least one battery cell in response to the variable-frequency voltage signal; and
sequentially switching the variable-frequency voltage signal to a next battery cell of the more than one battery cells according to the detection signal, and returning to the step of providing the variable-frequency voltage signal to the at least one battery cell.

12. The battery analysis method according to claim 11, wherein after the step of generating the detection signal, the battery analysis method further comprising:
determining whether the current connected battery cell is the last one of the more than one battery cells; and
if it is not, going to the step of switching the variable-frequency voltage signal to the next battery cell of the more than one battery cells according to the detection signal.

13. The battery analysis method according to claim 8, wherein the battery analysis method analyzes the battery module in real time in an online manner.
